(19) United States
(12) Patent Application Publication
(10) Pub. No.: US 2024/0203709 A1
(43) Pub. Date: Jun. 20, 2024

(54) SUBSTRATE PROCESSING METHOD AND SUBSTRATE PROCESSING DEVICE

(71) Applicant: JUSUNG ENGINEERING CO., LTD., Gwangju-Si, Gyeonggi-Do (KR)

(72) Inventors: Kyung Ran PARK, Gwangju-Si, Gyeonggi-Do (KR); Kwang Su PARK, Gwangju-Si, Gyeonggi-Do (KR); Won Uk CHAE, Gwangju-Si, Gyeonggi-Do (KR); Dong Hwan CHOI, Gwangju-Si, Gyeonggi-Do (KR); Cheol Young CHOI, Gwangju-Si, Gyeonggi-Do (KR)

(21) Appl. No.: 18/286,359

(22) PCT Filed: Apr. 8, 2022
(86) PCT No.: PCT/KR2022/005103

§ 371 Date: Oct. 10, 2023

(30) Foreign Application Priority Data
Apr. 9, 2021 (KR) 10-2021-0046543
Apr. 6, 2022 (KR) 10-2022-0042975

(51) Int. Cl. H01J 37/32; C23C 16/02; C23C 16/50; C23C 16/52; C30B 25/10; C30B 25/16; C30B 25/18; H01L 21/02

(52) U.S. Cl. CPC H01J 37/32862; C23C 16/0227; C23C 16/50; C23C 16/52; C30B 25/105; C30B 25/16; C30B 25/186; H01J 37/321; H01L 21/0262; H01L 21/02661; H01J 2237/335

(57) ABSTRACT

In accordance with an exemplary embodiment, a substrate processing method includes: a preparation process of seating a substrate on a support in a chamber; a first cleaning process of injecting a first cleaning gas into the chamber and removing a native oxide on the substrate; a growth process of injecting a process gas into the chamber and growing a thin film on a growth area on one surface of the substrate; and a process of generating inductively coupled plasma (ICP) in the chamber in the first cleaning process, and an inner temperature of the chamber is in a range from 300° C. to 750° C. Thus, in accordance with an exemplary embodiment, a cleaning process of removing the native oxide formed on the growth area of the substrate is performed before the growth process. Thus, a selective growth process may be easily performed on the substrate, and quality of the thin film may improve.

### TECHNICAL FIELD

The present disclosure relates to a substrate processing method and a substrate processing apparatus, and more particularly, to a substrate processing method and a substrate processing apparatus, which improve quality of a thin film.

### BACKGROUND ART

A process of manufacturing a semiconductor element includes a growth process of selectively growing an epitaxial layer on a substrate. Here, a pattern layer made of an oxide, e.g., SiO₂, is formed on a portion of a top surface of the substrate. Also, when a process gas is injected, selective growth in which a thin film is formed on an exposed area on which the pattern layer is not formed in the top surface of the substrate is performed.

While the substrate is transferred or in a standby state before a growth process, a native oxide may be formed on the top surface of the substrate. That is, the native oxide may be formed on the exposed area on which the pattern layer is not formed in the top surface of the substrate. Also, impurities may be deposited on the pattern layer during the growth process of injecting the process gas to the substrate.

The above-described native oxide and impurities act as factors of interrupting the selective growth. Thus, a thin film having a target thickness may not be formed, or thickness uniformity of the thin film may be degraded. Therefore, a performance of the semiconductor element may be degraded.

### RELATED ART DOCUMENT

### Patent Document

(patent document 1) Korean Patent Registration No. 10-1728072

### DISCLOSURE OF THE INVENTIVE CONCEPT

### Technical Problem

The present disclosure provides a substrate processing method and a substrate processing apparatus, which are capable of improving quality of a thin film.

The present disclosure also provides a substrate processing method and a substrate processing apparatus, which are capable of improving a substrate cleaning speed.

### Technical Solution

In accordance with an exemplary embodiment, a substrate processing method includes: a preparation process of seating a substrate on a support in a chamber; a first cleaning process of injecting a first cleaning gas into the chamber and removing a native oxide on the substrate; a growth process of injecting a process gas into the chamber and growing a thin film on a growth area on one surface of the substrate; and a process of generating inductively coupled plasma (ICP) in the chamber in the first cleaning process, and an inner temperature of the chamber is in a range from 300° C. to 750° C.

The first cleaning process may further include a process of removing an impurity produced in the process of removing the native oxide by injecting a second cleaning gas different from the first cleaning gas into the chamber.

The substrate processing method may further include a second cleaning process of removing an impurity remained on one surface of the substrate by injecting a second cleaning gas different from the first cleaning gas into the chamber.

The second cleaning process may include a process of generating inductively coupled plasma (ICP) in the chamber.

The substrate processing method may further include a chamber cleaning process that is performed in at least one of before the substrate is loaded into the chamber and after the substrate in the chamber is withdrawn to the outside, and the chamber cleaning process may include a process of injecting the second cleaning gas into the chamber.

The chamber cleaning process may include a process of generating inductively coupled plasma (ICP) in the chamber.

An intensity of a RF power applied to a plasma generation unit outside the chamber in order to generate the inductively coupled plasma (ICP) in the chamber cleaning process is different from that of a RF power applied in the first and second cleaning processes.

The growth process and the second cleaning process may be alternately performed a plurality of times.

In accordance with another exemplary embodiment, a substrate processing apparatus includes: a chamber; a support installed in the chamber to support a substrate; a plasma generation unit installed outside the chamber to generate inductively coupled plasma (ICP) in the chamber; and a controller configured to control an operation of the plasma generation unit so that the inductively coupled plasma (ICP) is generated in the chamber in a first cleaning process of injecting a first cleaning gas into the chamber before a growth process of growing a thin film on the substrate, and an inner temperature of the chamber is in a range from 300° C. to 750° C.

The controller may control the operation of the plasma generation unit so that the inductively coupled plasma (ICP) is generated in the chamber in a second cleaning process of injecting a second cleaning gas different from the first cleaning gas into the chamber after the growth process.

The controller may apply at least one of a first RF power and a second RF power, which are different from each other, to the plasma generation unit.

### Advantageous Effects

In accordance with the exemplary embodiments, the cleaning process of removing the native oxide formed on the growth area of the substrate is performed before the growth process. Thus, the selective growth process may be easily performed on the substrate, and the quality of the thin film may improve.

Also, when the plurality of growth processes are performed by injecting the process gas a plurality of times with a time difference, the cleaning process of removing the impurity deposited on the pattern layer is performed between the growth processes. Thus, the selective growth process may be easily performed in the next growth process, and the quality of the thin film may improve.

Also, when at least one of the cleaning processes is performed, the plasma is generated in the chamber. Thus, the speed of at least one of the cleaning process may improve, and the cleaning efficiency may improve. Thus, the total substrate processing process speed may improve.

### BRIEF DESCRIPTION OF THE DRAWINGS

FIG. 1 is a view illustrating a substrate processing apparatus in accordance with an exemplary embodiment;

FIG. 2 is a conceptual view illustrating an example of a substrate processed by the substrate processing apparatus in accordance with an exemplary embodiment;

FIG. 3 is a flowchart representing a substrate processing method in accordance with an exemplary embodiment; and

FIGS. 4 to 8 are process views illustrating the substrate processing method in accordance with an exemplary embodiment.

### MODE FOR CARRYING OUT THE INVENTIVE CONCEPT

Hereinafter, a substrate processing apparatus in accordance with an exemplary embodiment will be described with reference to the accompanying drawings. Here, for example, the substrate processing apparatus may be an apparatus for selectively growing an epitaxial thin film on a substrate.

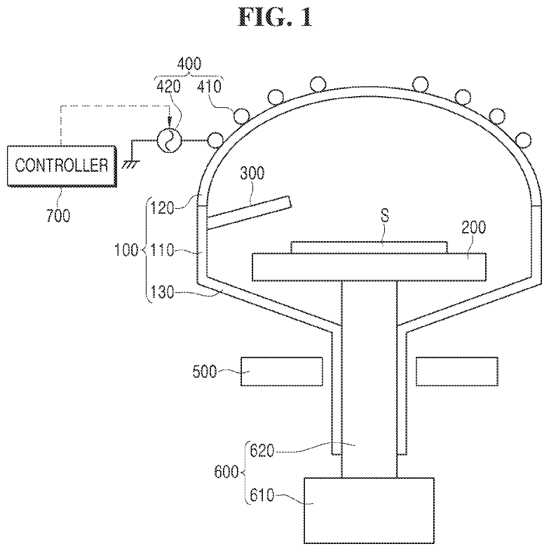

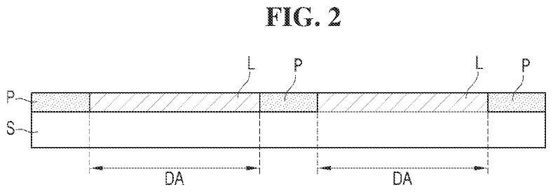

FIG. 1 is a view illustrating a substrate processing apparatus in accordance with an exemplary embodiment. FIG. 2 is a conceptual view illustrating an example of a substrate processed by the substrate processing apparatus in accordance with an exemplary embodiment.

Referring to FIG. 1, the substrate processing apparatus in accordance with an exemplary embodiment may include: a chamber 100 having an inner space; a support 200 installed in the chamber 100 to support a substrate S; an injection unit 300 installed in the chamber 100 to inject a gas into the chamber 100; a plasma generation unit 400 installed outside the chamber 100 to generate plasma in the chamber 100; and a controller 700 controlling an operation of the plasma generation unit 400.

Also, the substrate processing apparatus may include: a heating unit 500 having at least a portion facing the support 200; a driving unit 600 for elevating or rotating the support 200; an exhaust unit (not shown) for exhausting gases and impurities in the chamber 100.

The substrate S processed in the substrate processing apparatus may be, e.g., a wafer. More specifically, the substrate S may be a silicon (Si) wafer on which a thin film (hereinafter, referred to as a pattern layer P made of an oxide, e.g., SiO₂, is formed as in FIG. 2. In other words, the substrate S may have a top surface on which the pattern layer P made of SiO₂ is discontinuously formed. Thus, a portion of the top surface of the substrate may be covered by the SiO₂ pattern layer P, and the rest may be exposed.

On the substrate S, selective growth in which a thin film L is grown on an area, on which the pattern layer P is not formed, of the top surface is performed. The process of selectively growing the thin film L on the substrate S will be described later again.

Also, the exemplary embodiment is not limited to the Si wafer. For example, the substrate S may include various wafers such as a Ge wafer and a SiGe wafer. Furthermore, the exemplary embodiment is not limited to the wafer. For example, the substrate S may include glass, plastic, a film, and metal.

The chamber 100 may include a chamber body 110, an upper body 120 installed on the chamber body 110, and a lower body 130 installed below the chamber body 110. The chamber body 110 may have a container shape having opened upper and lower portions, the upper body 120 may be installed to cover the upper opening of the chamber body 110, and the lower body 130 may be installed to cover the lower opening of the chamber body 110. The upper body 120 may have a dome shape in which a height increases in a direction toward a width directional center thereof. The chamber, i.e., each of the chamber body 110, the upper body 120, and the lower body 130, may be made of a transparent material through which light is transmitted, e.g., quartz.

The support 200, as a unit having one surface, e.g., a top surface, supporting the substrate, may be installed in the chamber 100. The support 200 may have an area greater than that of the substrate S and have a shape corresponding to the substrate S, e.g., a rectangular shape or a circular shape. Alternatively, the support 200 may have an area equal to or less than that of the substrate S.

The driving unit 600 may be a unit for operating the support 200 to be elevated or rotated. The driving unit 600 may include a driving source installed at a lower outside of the chamber 100 to provide a power of at least one of elevation and rotation and a driving shaft 620 having one end connected to the support 200 and the other end connected to the driving source 610. In the driving unit 600, the driving shaft 620 and the support 200 connected thereto may perform at least one of elevation and rotation by an operation of the driving source 610.

The heating unit 500, as a unit for heating the support 200 and the inside of the chamber 100, may be installed outside the chamber 100. More specifically, the heating unit 500 may be installed at a lower outside of the chamber 100 so that at least a portion thereof faces the support 200. The heating unit 500 may include a plurality of lamps, and the plurality of lamps may be arranged in a width direction of the support 200. Also, the plurality of lamps may include a lamp emitting radiant heat such as a halogen lamp.

The injection unit 300 injects a gas toward the substrate S seated on the support 200 in the chamber 100. The injection unit 300 may be installed on the chamber 100 such that one end thereof from which a gas is injected is disposed inside the chamber 100. Here, as illustrated in FIG. 1, the injection unit 300 may be installed on a side portion, e.g., the chamber body 110, of the chamber 100 and may have a pipe shape through which a gas passes. Also, as illustrated in FIG. 1, the injection unit 300 may be inclined upward so that a height thereof gradually increases in a direction toward the one end from which a gas is injected.

However, the exemplary embodiment is not limited thereto. For example, the injection unit 300 may have various installation positions, arrangements, and shapes. That is, the injection unit 300 may be installed at any position as long as the one end from which a gas is injected faces the support 200. For example, the injection unit 300 may be installed on the upper body 120. Also, the injection unit 300 may be provided in a horizontal state instead of being inclined upward. However, the exemplary embodiment is not limited to the pipe shape of the injection unit 300. For example, the injection unit 300 may have various shapes for injecting a gas toward the substrate S.

The gas injected from the injection unit 300 may be a gas (hereinafter, referred to as a process gas) for forming or growing the thin film L on the substrate S or a gas (hereinafter, referred to as a cleaning gas) for cleaning the substrate S or the inside of the chamber 100.

The process gas, as a gas injected to grow the thin film L on the substrate S, may be changed according to the kind of the substrate S or the thin film to be grown. For example, when the substrate S is a Si wafer, and the thin film L made of Si is grown on the substrate S, the process gas may be a Si-containing gas. Also, when the substrate S is a Ge wafer, and the thin film L made of Ge is grown on the substrate S, the process gas may be a Ge-containing gas. For another example, when the substrate S is a SiGe wafer, and the thin film L made of SiGe is grown on the substrate S, the process gas may be a Si-containing gas and a Ge-containing gas. Here, the Si-containing gas may include at least one of Si₂H₆ and SiH₄. Also, the Ge-containing gas may include GeH₄. Also, the injection unit 300 may additionally inject a boron (B)-containing gas for additional doping. Here, the B-containing gas may include, e.g., B₂H₆.

As illustrated in FIG. 2, the thin film type pattern layer P made of an oxide, e.g., SiO₂, is formed on a portion of the top surface of the substrate S as described above. Thus, a portion of the top surface of the substrate S facing the injection unit 300 is covered by the pattern layer P, and the rest is exposed.

Here, the pattern layer P made of an oxide may serve as a mask that interrupts or prevents deposition or growth. That is, the pattern layer P may be a unit for allowing selective growth or film formation. Thus, when the process gas, e.g., a Si₂H₆-containing gas, is injected from the injection unit 300, Si₂H₆ is decomposed or dissociated by heat in the chamber 100, and decomposed Si is deposited on the substrate S. That is, as Si is deposited on an exposed area (hereinafter, referred to as a growth area DA) on which the pattern layer P is not formed in the top surface of the substrate S, the thin film L made of Si is grown or formed. In other words, selective growth in which Si is deposited on the growth area on which the pattern layer P is not formed in the top surface of the substrate S may be performed.

However, as the growth area DA of the substrate S is oxidized before the growth process is performed, a thin oxide layer, i.e., a native oxide, may be formed on the growth area DA. That is, while the substrate S is transferred to the chamber or on standby at the outside of the chamber 100, as the growth area DA is oxidized, the native oxide may be formed. This native oxide may act as a cause of interrupting growth or formation of the thin film. Thus, the native oxide formed on the growth area DA of the substrate S may be required to be removed before the growth process is performed.

Also, while the thin film L is formed or grown on the substrate S, impurities may be remained on the pattern layer P. That is, a small amount of material produced from the process gas may be also attached and remained on the pattern layer P in addition to the growth area DA of the substrate S, and the material remained on the pattern layer P may act as impurities. For example, when the process gas contains Si₂H₆, a small amount of Si may be remained on the pattern layer P while the thin film made of Si is deposited on the growth area DA of the substrate S. The material remained on the pattern layer P, i.e., Si, acts as impurities interrupting selective growth in a next growth process. Thus, the impurities such as Si remained on the pattern layer P may be required to be removed.

Thus, in accordance with an exemplary embodiment, a cleaning process (hereinafter, referred to as a first cleaning process) of removing the native oxide formed on the growth area DA of the substrate S is performed before the growth process of growing the thin film L on the substrate S, and a cleaning process (hereinafter, referred to as a second cleaning process) of removing the impurities remained on the pattern layer P is performed after the growth process.

Here, a cleaning gas injected in the first cleaning process may include a first cleaning gas. Also, the cleaning gas injected in the first cleaning process may further include a second cleaning gas that contains a material different from that of the first cleaning gas. Also, a cleaning gas injected in the second cleaning process may include the second cleaning gas. Here, the first cleaning gas may include SF₆, and the second cleaning gas may include Cl₂.

Also, when a substrate processing process is performed a plurality of times in the chamber 100, by-products produced from the process gas may be generated in the chamber 100, and the by-products may be deposited on an inner wall of the chamber 100 and a surface of the support 200. For example, when Si₂H₆ is used as the process gas, by-products made of Si may be deposited on the inner wall of the chamber 100 and the surface of the support 200. The by-products may act as impurities degrading quality of the thin film L or a product Thus, the cleaning process of removing the impurities in the chamber may be required.

For example, the inside of the chamber 100 is cleaned after the substrate processing process is performed a plurality of times, before the substrate S is loaded into the chamber 100, or after the substrate S in the chamber 100 is withdrawn to the outside. Here, the inside of the chamber 100 is cleaned by injecting the Cl₂-containing second cleaning gas through the injection unit 300.

The first cleaning process, the growth process, the second cleaning process, and the process of cleaning the chamber 100 will be described later again.

The plasma generation unit 400 is disposed at an upper portion of the chamber 100, i.e., at an upper portion of the upper body 120, to ionize the gas supplied into the chamber 100, thereby generating plasma. The plasma generation unit 400 may generate inductively coupled plasma (ICP). That is, as illustrated in FIG. 1, the plasma generation unit 400 may include an antenna including a coil 410 for inducing an electric field in the chamber 100 and a power part 420 connected with the coil 410 to apply a RF power.

The coil 410 may be installed at the upper portion of the upper body 120. Here, the coil 410 may include a plurality of circular coils provided in a spiral shape wound with a plurality of turns or arranged in a concentric circle shape to be connected with each other. However, the exemplary embodiment is not limited to the shape of the coil 410. For example, the coil 410 may have various shapes in addition to the spiral coil or the circular coil on the concentric circle.

Also, the coil 410 may have a double layer structure including a lower coil adjacent to the upper portion of the upper body 120 and an upper coil spaced upward from lower coil.

The coil 410 may be made of a conductive material such as copper and manufactured into a hollow pipe shape. When the coil 410 has the pipe shape, temperature increase of the coil may be constrained because coolant or refrigerant flows therethrough.

Also, one end of both ends of the coil 410 may be connected to the power part 420, and the other may be connected to a ground terminal. Thus, when a RF power is applied to the coil through the power part 420, the gas injected into the chamber 100 may be ionized or discharged to generate plasma in the chamber 100.

The controller 700 may control an operation of the plasma generation unit 400. More specifically, the controller 700 may control the plasma generation unit 400 to generate plasma in the chamber 100 in at least one of the first cleaning process and the second cleaning process.

Also, the controller 700 may control the plasma generation unit 400 to generate plasma in the chamber 100 when the process of cleaning the inside of the chamber 100 is performed before the substrate S is loaded into the chamber 100 or after the completely processed substrate S is withdrawn from the chamber 100.

The controller 700 may adjust an intensity of the RF power applied to the power part 420 of the plasma generation unit 400 during the chamber cleaning process to be different from that of the RF power applied during the first and second cleaning process. For example, the controller may adjust the intensity of the RF power applied to the power part 420 during the chamber cleaning process to be greater than that of the RF power applied during the first and second cleaning process. In other words, the controller 700 may adjust an intensity of a first RF power applied to the power part 420 during the first and second cleaning process to be different from that of a second RF power applied during the chamber cleaning process, and the intensity of the first RF power may be greater than that of the second RF power.

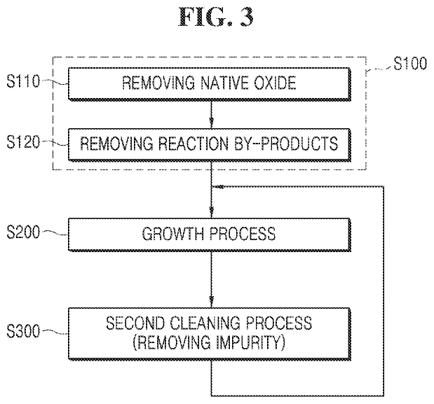

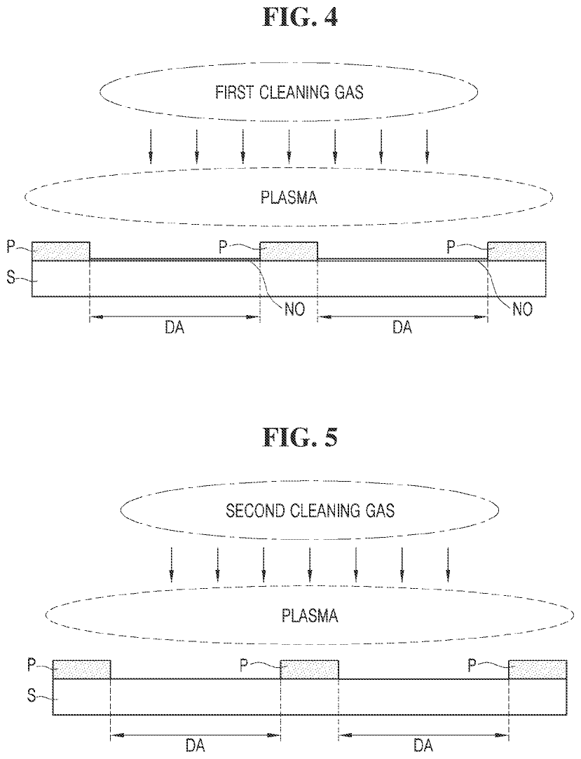

FIG. 3 is a flowchart representing a substrate processing method in accordance with an exemplary embodiment. FIGS. 4 to 8 are process views illustrating the substrate processing method in accordance with an exemplary embodiment.

Hereinafter, the substrate processing method in accordance with an exemplary embodiment will be described with reference to FIGS. 3 to 8. Here, a method for growing a thin film made of Si on a growth area of a substrate when the substrate is a Si wafer will be described as an example.

Firstly, a support 200 is heated to a temperature for a process (hereinafter, referred to as a process temperature), e.g., a temperature of 550° C., by operating a heating unit 500. When the support 200 reaches to the process temperature, the substrate S is loaded into the chamber 100 and seated on the support 200 (a preparation process).

An inner pressure of the chamber 100 may be set or controlled in a pressure range equal to or less than several mtorr, equal to or less than several tens mtorr, or equal to or less than several hundreds mtorr before or after the substrate S is seated on the support 200. Also, the inner pressure of the chamber 100 may be set or controlled in a pressure range equal to or less than several mtorr, equal to or less than several tens mtorr, or equal to or less than several hundreds mtorr in at least one of a first cleaning process S100, a growth process S200, and a second cleaning process S300.

Also, an inner temperature of the chamber 100 may be set or controlled in a range from 300° C. to 750° C. (300° C. or more to 750° C. or less), more preferably in a range from 400° C. to 600° C. (400° C. or more to 600° C. or less) before or after the substrate S is seated on the support 200. Also, the inner temperature of the chamber 100 may be set or controlled in a range from 300° C. to 750° C., more preferably in a range from 400° C. to 600° C. in at least one of the first cleaning process S100, the growth process S200, and the second cleaning process S300. Here, the inner temperature of the chamber 100 may be set or controlled by using the heating unit 500.

When the substrate S is seated on the support 200, the first cleaning process including a process S110 of removing a native oxide NO formed on the substrate S in the process S100. To this end, as illustrated in FIG. 4, a first cleaning gas, e.g., SF₆-containing gas, is injected through an injection unit 300. Also, a controller 700 allows a power part 720 of a plasma generation unit 400 to apply a RF power, thereby generating plasma in the chamber 100. Here, the controller 700 may adjust an intensity, i.e., an electric power, of the RF power applied to a coil 410 through a power part 420 in a range, e.g., from 60 W to 1000 W.

When the first cleaning gas containing SF₆ is injected into the chamber 100, the SF₆ and the native oxide NO react with each other by the plasma generated by the plasma generation unit 400 and inner heat of the chamber 100 caused by the support 200. That is, the SF₆ reacts with oxygen (O) of the native oxide NO to generate SO₂. Also, the SO₂ that is a reaction product may be discharged to the outside through an exhaust unit. Thus, the native oxide NO formed on the substrate S is removed.

When the first cleaning gas containing SF₆ is injected into the chamber 100 as described above, a pattern layer P made of an oxide as well as the native oxide NO formed on a growth area DA of the substrate S may react with the first cleaning gas. Thus, a portion of the pattern layer P may be also etched by the first cleaning gas. However, since the native oxide NO has an extremely thin thickness, and the pattern layer P has a thick thickness, a small amount of thickness of the pattern layer P may be etched by the first cleaning gas. Thus, when the native oxide NO formed on a growth area DA is removed by the first cleaning gas, the pattern layer P is remained (refer to FIG. 5).

As described above, in an exemplary embodiment, plasma is generated by operating the plasma generation unit 400 while injecting the first cleaning gas into the chamber 100. That is, plasma is additionally generated in the chamber 100 in addition to heating the support 200 in the chamber 100. When the plasma is generated in the chamber 100, a reaction speed between the first cleaning gas and the native oxide NO increases. That is, when plasma is generated, a decomposition speed of the SF₆ is faster than that of a case when plasma is not generated, and thus a reaction speed with the native oxide NO is fast. Thus, the reaction speed may improve in the case when plasma is generated more than the case when plasma is not generated. Thus, a time for the first cleaning process of removing the native oxide NO formed on the growth area DA of the substrate S may be reduced, and a cleaning efficiency may improve.

When the first cleaning gas reacts with the native oxide in the process S110 of removing the native oxide, reaction by-products including a component decomposed from the first cleaning gas may be produced. That is, when SF₆ of the first cleaning gas reacts with the native oxide NO to produce SO₂, fluorine (F) may be decomposed from the first cleaning gas, and thus by-products including the fluorine (F) may be remained in the chamber 100. Also, the fluorine (F) in the chamber 100 may degrade quality of a thin film L or a product. Thus, after the process S110 of removing the native oxide NO, the by-products remained in the chamber 10, i.e., fluorine (F), may be removed in a process S120.

To this end, as illustrated in FIG. 5, after the process S110 of removing the native oxide NO by injecting the first cleaning gas, a second cleaning gas containing Cl₂ is generated into the chamber 100 through the injection unit 300 to generate plasma. Here, the controller 7000 may adjust an electric power applied to the coil 410 through the power part 420 to be equal to that of when the first cleaning gas is injected, e.g., in a range from 60 W to 1000 W.

When the second cleaning gas containing Cl₂ is injected into the chamber 100, the Cl₂ and the by-products, i.e., fluorine (F), react with each other by the plasma generated by the plasma generation unit 400 and the inner heat of the chamber 100 caused by the support 200. Also, CIF produced by the reaction between the second cleaning gas and the fluorine (F) is discharged to the outside through the exhaust unit. Thus, the by-products produced by the first cleaning gas in the process S110 of removing the native oxide are removed to the outside of the chamber 100 in the process S120.

As described above, when the plasma is generated while the second cleaning gas is injected, a reaction speed between the second cleaning gas and the fluorine (F) may improve. That is, when plasma is generated, a decomposition speed of the Cl₂ is faster than that of a case when plasma is not generated, and thus a reaction speed with the fluorine (F) is fast. Thus, the reaction speed may improve in the case when plasma is generated more than the case when plasma is not generated. Thus, a time for the process of removing the by-products, i.e., the fluorine (F), remained in the chamber 100 after the first cleaning process may be reduced, and the cleaning efficiency may improve.

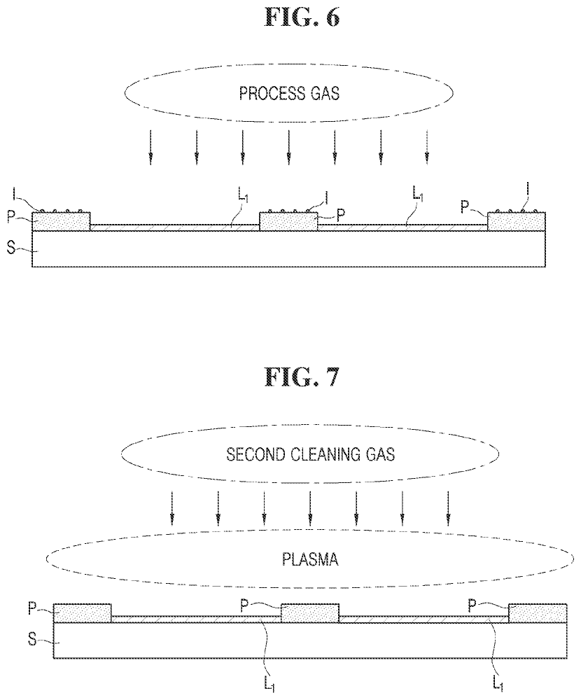

When the first cleaning process is finished, the growth process S200 of forming the thin film on the growth area DA of the substrate is performed. To this end, as illustrated in FIG. 6, a process gas, e.g., a gas containing Si₂H₆, is injected through the injection unit 300. Here, Si is decomposed or dissociated from the Si₂H₆ of the process gas by the inner heat of the chamber 100, and the decomposed Si is deposited on the growth area DA of the substrate S. Thus, as illustrated in FIG. 6, a thin film (a first thin film L₁) made of Si is formed on the growth area DA of the substrate S.

However, during the growth process of forming the thin film on the substrate S, a small amount of material produced from the process gas may be remained on the pattern layer P as well as the growth area DA of the substrate S. For example, when the process gas containing Si₂H₆ is injected, and a thin film made of Si is deposited on the growth area DA of the substrate S, a small amount of Si may be attached and remained on the pattern layer P. The Si remained on the pattern layer P acts as impurities in a next growth process. Thus, the second cleaning process S300 of removing an impurity I remained on the pattern layer P is performed when the growth process is finished.

Through this, as illustrated in FIG. 7, a second cleaning gas, e.g., a Cl₂-containing gas, is injected through the injection unit 300. Also, the controller 700 allows the power part 420 of the plasma generation unit 400 to apply a RF power, thereby generating plasma in the chamber 100. Here, the controller 700 may adjust a RF power, i.e., an electric power, applied to the coil 410 through the power part 420 in a range, e.g., from 60W to 1000 W.

When the second cleaning containing Cl₂ is injected into the chamber 100, the Cl₂ and Si react with each other by the plasma generated in the chamber 00 and the inner heat of the chamber 100 caused by the support 200. Also, by-products SiCl4 are discharged to the outside through the exhaust unit. Thus, the impurity I on the pattern layer P is removed.

When the second cleaning gas is injected into the chamber 100, the impurities remained on the pattern layer P as well as the first thin film L₁ formed on the growth area DA of the substrate S may react with the second cleaning gas. Thus, a portion of the first thin film L₁ may be also etched by the second cleaning gas. However, since the impurity I has an extremely thin thickness, and the first thin film L₁ has a relatively thick thickness, a small amount of thickness of the first thin film L₁ may be etched by the second cleaning gas. Thus, when the impurity I on the pattern layer P is etched or removed by the second cleaning gas, the first thin film L₁ is remained.

As described above, as plasma is generated in the second cleaning process of removing the impurity on the pattern layer P by injecting the second cleaning gas, a reaction speed between the second cleaning gas and the impurity I may improve. That is, when plasma is generated, a decomposition speed of the Cl₂ is faster than that of a case when plasma is not generated, and thus a reaction speed with the impurity I is fast. Thus, the reaction speed may improve in the case when plasma is generated than the case when plasma is not generated. Thus, a time for the second cleaning process may be reduced to be less than the process time. That is, the second cleaning process may be performed during a time less than that of the growth process. Thus, the cleaning efficiency may improve, the total process time may be reduced, and a damage of the substrate or the thin film according to the second cleaning process may be prevented.

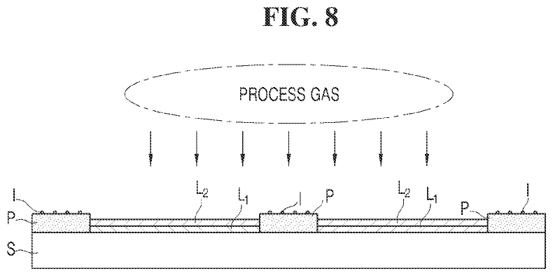

When the second cleaning process is finished, the above-described growth process S200 is performed in the same method. Thus, as illustrated in FIG. 8, a second thin film L₂ is formed on the first thin film L₁. Also, during the growth process S200 of forming the second thin film L₂ on the first thin film L₁, the impurity I may be attached or remained on the pattern layer P. Thus, when the growth process S200 of forming the second thin film L₂ is finished, the second cleaning process S300 is performed in the same method that is described above.

Also, the growth process S200 and the second cleaning process S300 are alternately and repeatedly performed a plurality of times until the thin film having a target thickness is formed on the growth area DA of the substrate S. Thus, the thin film having the target thickness is grown on the growth area DA of the substrate S as illustrated in FIG. 2.

Also, as described above, the process of forming the thin film L on the substrate S is repeated a plurality of times, and then the process of cleaning the inside of the chamber 100 is performed. That is, the inside of the chamber 100 is cleaned before the substrate S is loaded into the chamber 100 or after the substrate S in the chamber 100 is withdrawn to the outside. To this end, the second cleaning gas containing Cl₂ is injected into the chamber 100 through the injection unit 300, and the plasma is generated by applying the RF power from the power part 420 of the plasma generation unit 400. Here, the controller 700 adjusts an intensity, i.e., an electric power, of the RF power applied to the coil 410 through the power part 420 to be greater than that applied in each of the first cleaning process and the second cleaning process.

When the second cleaning gas is injected into the chamber 100, and the plasma is generated, the Cl₂ of the second cleaning gas and the impurity, e.g., Si, remained in the chamber 100 react with each other. The reaction product SiCl4 is discharged to the outside through the exhaust unit, and thus the impurity in the chamber is removed. That is, the inside of the chamber 100 is cleaned.

In accordance with the substrate process processing method, the first cleaning process of removing the native oxide NO formed on the growth area DA of the substrate S is performed before the growth process. Thus, the selective growth process may be easily performed on the substrate S, and the quality of the thin film may improve.

When a plurality of growth processes are performed by injecting the process gas a plurality of times with a time difference, the second cleaning process of removing the impurity I remained on the pattern layer is performed between the growth processes. Thus, the selective growth process may be easily performed in a next growth process, and the quality of the thin film may improve.

Also, when at least one of the first cleaning process and the second cleaning process is performed, the plasma is generated in the chamber 100. Thus, a speed of at least one of the first cleaning process of removing the native oxide on the substrate S and the second cleaning process of removing the impurity on the pattern layer P may improve, and the cleaning efficiency may improve. Thus, a total substrate processing process speed may improve.

Also, the inner pressure of the chamber 100 may be set or controlled in a pressure range equal to or less than several mtorr, equal to or less than several tens mtorr, or equal to or less than several hundreds mtorr when at least one of the first cleaning process, the growth process, and the second cleaning process is performed. Thus, at least one of the first cleaning process, the growth process, and the second cleaning process may be easily performed at a temperature lower than that of the related art. Also, as the inner pressure of the chamber 100 is set or controlled in a pressure range equal to or less than several mtorr, equal to or less than several tens mtorr, or equal to or less than several hundreds mtorr, a concentration of impurities such as oxygen in the chamber 100 may be reduced, and thus, the quality of the thin film may improve.

In accordance with the exemplary embodiments, the cleaning process of removing the native oxide formed on the growth area of the substrate is performed before the growth process. Thus, the selective growth process may be easily performed on the substrate, and the quality of the thin film may improve.

Also, when the plurality of growth processes are performed by injecting the process gas a plurality of times with a time difference, the cleaning process of removing the impurity deposited on the pattern layer is performed between the growth processes. Thus, the selective growth process may be easily performed in the next growth process, and the quality of the thin film may improve.

Also, when at least one of the cleaning processes is performed, the plasma is generated in the chamber. Thus, the speed of at least one of the cleaning process may improve, and the cleaning efficiency may improve. Thus, the total substrate processing process speed may improve.

Although the embodiments of the present inventive concept have been described, it is understood that the present inventive concept should not be limited to these embodiments but various changes and modifications can be made by one ordinary skilled in the art within the spirit and scope of the present inventive concept as hereinafter claimed.

### INDUSTRIAL APPLICABILITY

In accordance with the exemplary embodiments, the cleaning process of removing the native oxide formed on the growth area of the substrate is performed before the growth process. Thus, the selective growth process may be easily performed on the substrate, and the quality of the thin film may improve.

What is claimed is:

1. A substrate processing method comprising:
a preparation process of seating a substrate on a support in a chamber;
a first cleaning process of injecting a first cleaning gas into the chamber and removing a native oxide on the substrate;
a growth process of injecting a process gas into the chamber and growing a thin film on a growth area on one surface of the substrate; and
a process of generating inductively coupled plasma (ICP) in the chamber in the first cleaning process,
wherein an inner temperature of the chamber is in a range from 300° C. to 750° C.

2. The substrate processing method of claim 1, wherein the first cleaning process further comprises a process of removing an impurity produced in the process of removing the native oxide by injecting a second cleaning gas different from the first cleaning gas into the chamber.

3. The substrate processing method of claim 1, further comprising a second cleaning process of removing an impurity remained on one surface of the substrate by injecting a second cleaning gas different from the first cleaning gas into the chamber.

4. The substrate processing method of claim 3, wherein the second cleaning process comprises a process of generating inductively coupled plasma (ICP) in the chamber.

5. The substrate processing method of claim 4, further comprising a chamber cleaning process that is performed in at least one of before the substrate is loaded into the chamber and after the substrate in the chamber is withdrawn to the outside, wherein the chamber cleaning process comprises a process of injecting the second cleaning gas into the chamber.

6. The substrate processing method of claim 5, wherein the chamber cleaning process comprises a process of generating inductively coupled plasma (ICP) in the chamber.

7. The substrate processing method of claim 6, wherein an intensity of a RF power applied to a plasma generation unit outside the chamber in order to generate the inductively coupled plasma (ICP) in the chamber cleaning process is different from that of a RF power applied in the first and second cleaning processes.

8. The substrate processing method of claim 3, wherein the growth process and the second cleaning process are alternately performed a plurality of times.

9. A substrate processing apparatus comprising:
a chamber;
a support installed in the chamber to support a substrate;
a plasma generation unit installed outside the chamber to generate inductively coupled plasma (ICP) in the chamber; and
a controller configured to control an operation of the plasma generation unit so that the inductively coupled plasma (ICP) is generated in the chamber in a first cleaning process of injecting a first cleaning gas into the chamber before a growth process of growing a thin film on the substrate,
wherein an inner temperature of the chamber is in a range from 300° C. to 750° C.

10. The substrate processing apparatus of claim 9, wherein the controller controls the operation of the plasma generation unit so that the inductively coupled plasma (ICP) is generated in the chamber in a second cleaning process of injecting a second cleaning gas different from the first cleaning gas into the chamber after the growth process.

11. The substrate processing apparatus of claim 10, wherein the controller applies at least one of a first RF power and a second RF power, which are different from each other, to the plasma generation unit.
